(19) United States
(12) Patent Application Publication
(10) Pub. No.: US 2026/0214758 A1
(43) Pub. Date: Jul. 23, 2026

(54) INDUCTION COIL ASSEMBLY DRIVE SYSTEM, CONTROL METHOD THEREOF, AND SEMICONDUCTOR PROCESSING EQUIPMENT

(71) Applicant: BEIJING NAURA MICROELECTRONICS EQUIPMENT CO., LTD., Beijing (CN)

(72) Inventor: Jian WANG, Beijing (CN)

(21) Appl. No.: 19/134,166

(22) PCT Filed: Nov. 20, 2023
(86) PCT No.: PCT/CN2023/132568

§ 371 Date: May 29, 2025

(30) Foreign Application Priority Data
Nov. 30, 2022 (CN) 202211519132.6

(51) Int. Cl. H05B 6/40; H05B 6/10

(52) U.S. Cl. CPC H05B 6/40; H05B 6/10

(57) ABSTRACT

Embodiments of the present disclosure provide an induction coil assembly drive system, a control method of the induction coil assembly drive system, and semiconductor processing equipment. The induction coil assembly drive system includes a rotary driver and a lifting assembly. The rotary driver is drivingly connected to the induction coil assembly through the lifting assembly to drive the induction coil assembly. The system further includes a controller configured to, based on the target lifting speed of the induction coil assembly within the predetermined time length, determine a theoretical rotation speed of the rotary driver based on a target lifting speed of the induction coil assembly within a predetermined time length, wherein the theoretical rotation speed is a speed at which the rotary driver operates uniformly within the predetermined time length, determine whether the theoretical rotation speed of the rotary driver is less than or equal to a predetermined rotation speed, wherein the predetermined rotation speed is a critical rotation speed at which the rotary driver generates vibration, and in response to the theoretical rotation speed of the rotary driver being less than or equal to the predetermined rotation speed, control the rotary driver to alternately stop and operate at the target rotation speed within the predetermined time length to cause an average speed of the rotary driver within the predetermine time length to be equal to the theoretical rotation speed, wherein the target rotation speed is greater than the predetermined rotation speed.

### TECHNICAL FIELD

The present disclosure generally relates to the drive device technology field and, more particularly, to an induction coil assembly drive system, a control method of the induction coil assembly drive system, and semiconductor processing equipment.

### BACKGROUND

In an implementation process of semiconductor processing, an induction coil assembly needs to be configured to heat a to-be-heated device, and a drive device is configured to drive the induction coil assembly to move to heat members of the to-be-heated device. With reference to FIG. 1, for example, in a process of preparing crystal based on a physical vapor transport process method (PVT), the induction coil assembly 10 needs to move outside crystal preparation equipment 20 to heat the crystal preparation equipment 20 according to a processing requirement.

In the related technology, a rotary driver and a lifting assembly are configured to drive the induction coil assembly 10 to move up and down. However, the rotary driver generally has an applicable speed range. When the induction coil assembly 10 needs to move at a relatively low speed, motion accuracy of an output end of the rotary driver decreases. Thus, the rotary driver cannot accurately drive the induction coil assembly 10 to move.

### SUMMARY

Embodiments of the present disclosure provide an induction coil assembly drive system, a control method of the induction coil assembly drive system, and semiconductor processing equipment to solve the problem of improving the drive precision of the rotary driver.

On a first aspect, embodiments of the present disclosure provide an induction coil assembly drive system.

The induction coil assembly drive system of embodiments of the present disclosure is applied to the semiconductor processing equipment and includes:
a rotary driver; and
a lifting assembly, the rotary driver being drivingly connected to the lifting assembly, and the lifting assembly being configured to be transmission-connected to an induction coil assembly to drive the induction coil assembly to move up and down;
a controller configured to:
   determine a theoretical rotation speed of the rotary driver based on a target lifting speed of the induction coil assembly within a predetermined time length, wherein the theoretical rotation speed is a speed at which the rotary driver operates uniformly within the predetermined time length;
   determine whether the theoretical rotation speed of the rotary driver is less than or equal to a predetermined rotation speed, wherein the predetermined rotation speed is a critical rotation speed at which the rotary driver generates vibration; and
   in response to the theoretical rotation speed of the rotary driver being less than or equal to the predetermined rotation speed, control the rotary driver to alternately stop and operate at the target rotation speed within the predetermined time length to cause an average speed of the rotary driver within the predetermine time length to be equal to the theoretical rotation speed, wherein the target rotation speed is greater than the predetermined rotation speed.

In some embodiments, the controller is further configured to, within the predetermined time length, in response to the theoretical rotation speed of the rotary driver being less than or equal to the predetermined rotation speed:
control the rotary driver to switch to a stop state for a plurality of times, wherein the rotary driver remains a first time length each time in the stop state; and
control a number of times for the rotary driver switching to operate at the target rotation speed to be same as a number of times for the rotary driver switching to stop, wherein the rotary driver remains a second time length in an operation state at the target rotation speed each time;
wherein a sum of a cumulative time length of the rotary driver being in the stop state and a cumulative time length of the rotary driver being in the operation state is equal to the predetermined time length.

In some embodiments, the controller is further configured to control the rotary driver to operate at the theoretical rotation speed within the predetermined time length in response to the theoretical rotation speed being greater than the predetermined rotation speed to drive the induction coil assembly to move up and down.

In some embodiments, the lifting assembly includes a screw rod and a slider, wherein the slider is threadedly connected to the screw rod to drive the slider to move using the rotating screw rod; and the rotary driver is drivingly connected to the screw rod to drive the screw rod to rotate, and the slider is configured to be connected to the induction coil assembly.

In some embodiments, the induction coil assembly drive system further includes a rotary encoder, wherein the rotary encoder is connected to the screw rod and electrically connected to the controller.

In some embodiments, the induction coil assembly drive system further includes a decelerator, wherein the rotary driver is drivingly connected to the screw rod through the decelerator.

In some embodiments, the decelerator includes a first sub-decelerator and a second sub-decelerator, wherein the second sub-decelerator is a reversing decelerator and includes a second power output shaft; the rotary driver is drivingly connected to the first sub-decelerator, the first sub-decelerator is drivingly connected to the second sub-decelerator, the second power output shaft is arranged along a height direction of the induction coil assembly drive system, and the screw rod is coaxially connected to the second power output shaft.

In some embodiments, the first sub-decelerator includes a first power output shaft, and the induction coil assembly drive system further includes an Electromagnetic brake, the Electromagnetic brake including a magnetic fixing member and a magnetic adsorption member, the magnetic adsorption member being circumferentially connected to the first power output shaft in a position-limiting manner, when the electromagnetic brake switches from a power-on state to a power-off state, the magnetic adsorption member switching from a separated state to an engaged state with the magnetic fixing member.

On a second aspect, embodiments of the present disclosure provide a control method of the induction coil assembly drive system.

The induction coil assembly drive system of embodiments of the present disclosure is applied to any induction coil assembly drive system of embodiments of the present disclosure.

The control method of the induction coil assembly drive system can include:
determining the theoretical rotation speed of the rotary driver by the controller based on the target lifting speed of the induction coil assembly within the predetermined time length, the theoretical rotation speed being the speed at which the rotary driver uniformly operates within the predetermined time length;
determining whether the theoretical rotation speed of the rotary driver is less than or equal to the predetermined rotation speed by the controller, wherein the predetermined rotation speed is a critical speed at which the rotary driver generates vibration; and
in response to the theoretical rotation speed of the rotary driver being less than or equal to the predetermined rotation speed, controlling the rotary driver to alternately stop and operate at the target rotation speed within the predetermined time length by the controller to cause the average rotation speed of the rotary driver within the predetermined time length to be equal to the theoretical rotation speed, wherein the target speed is greater than the predetermined rotation speed.

In some embodiments, the control method of the induction coil assembly drive system further includes, in response to the theoretical rotation speed being greater than the predetermined rotation speed, controlling the rotary driver to operate at the theoretical rotation speed within the predetermined time length to drive the induction coil assembly to move up and down by the controller.

On a third aspect, embodiments of the present disclosure provide semiconductor processing equipment including an induction coil assembly drive system. The induction coil assembly drive system includes:
a rotary driver; and
a lifting assembly, the rotary driver being drivingly connected to the lifting assembly, and the lifting assembly being configured to be transmission-connected to an induction coil assembly to drive the induction coil assembly to move up and down;
a controller including a processor and a readable storage medium, the readable storage medium storing a program or an instruction that, when executed by the processor, causes the processor to:
   determine a theoretical rotation speed of the rotary driver based on a target lifting speed of the induction coil assembly within a predetermined time length, wherein the theoretical rotation speed is a speed at which the rotary driver operates uniformly within the predetermined time length;
   determine whether the theoretical rotation speed of the rotary driver is less than or equal to a predetermined rotation speed, wherein the predetermined rotation speed is a critical rotation speed at which the rotary driver generates vibration; and
   in response to the theoretical rotation speed of the rotary driver being less than or equal to the predetermined rotation speed, control the rotary driver to alternately stop and operate at the target rotation speed within the predetermined time length to cause an average speed of the rotary driver within the predetermine time length to be equal to the theoretical rotation speed, wherein the target rotation speed is greater than the predetermined rotation speed.

On a fourth aspect, embodiments of the present disclosure provide a readable storage medium.

The readable storage medium of embodiments of the present disclosure can be applied to any induction coil assembly drive system of embodiments of the present disclosure. The readable storage medium includes programs or instructions that, when the programs and instructions are executed by a processor, cause the processor to implement the steps of any control method of the induction coil assembly drive system of embodiments of the present disclosure.

Embodiments of the present disclosure can apply at least one technical solution above to achieve the following beneficial effects.

In embodiments of the present disclosure, the rotary driver can alternatively stop and operate at the target rotation speed to cause the average rotation speed of the rotary driver within the predetermined time length to be equal to the theoretical rotation speed to ensure that the lifting speed of the induction coil assembly satisfies the requirements. When the rotary driver operates at the target rotation speed, the target rotation speed can be greater than the critical rotation speed at which the rotary driver generates the vibration. Then, the rotary driver can be prevented from generating vibration to improve the drive precision of the rotary driver. Thus, the rotary driver and the lifting assembly can be configured to drive the induction coil assembly to move up and down precisely.

### BRIEF DESCRIPTION OF THE DRAWINGS

The In order to more clearly illustrate the technical solutions in the embodiments of the present disclosure or the related technology, the drawings used in the description of the embodiments or related technology will be briefly introduced below. Obviously, the drawings described below are only some embodiments recorded in the present disclosure. For those of ordinary skill in the art, other drawings can also be obtained based on these drawings without creative effort.

FIG. 1 is a schematic diagram of an induction coil assembly and crystal preparation equipment according to an embodiment of the present disclosure.

FIG. 2 is a schematic diagram of an induction coil assembly drive system according to an embodiment of the present disclosure.

FIG. 3 is a schematic diagram of an induction coil assembly according to an embodiment of the present disclosure.

FIG. 4 is a schematic diagram of a drive mechanism according to an embodiment of the present disclosure.

FIG. 5 is a schematic local cross-section diagram of an induction coil assembly drive system according to an embodiment of the present disclosure.

FIG. 6 is a schematic flowchart of a control method of an induction coil assembly drive system according to an embodiment of the present disclosure.

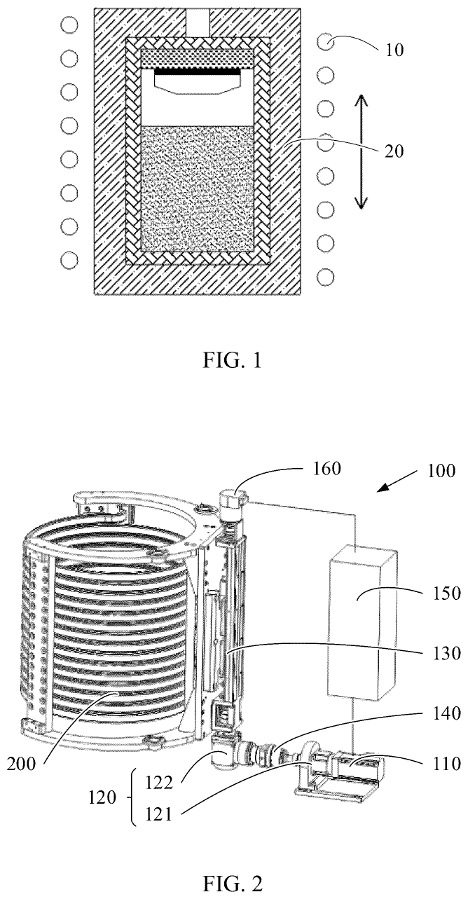

### REFERENCE NUMERALS

| 10 Induction coil assembly | 20 Crystal preparation equipment | |
|---|---|---|
| 100 Induction coil assembly | 110 Rotary driver | 120 Decelerator |
| drive system | | |
| 121 First sub-decelerator | 122 Second sub- | |
| | decelerator | |
| 130 Lifting assembly | 131 Screw rod | 132 Slider |
| 140 Electromagnetic brake | 141 Magnetic fixing | |
| | member | |
| 142 Magnetic adsorption | 150 Controller | 160 Rotation |
| member | | encoder |
| 200 Induction coil assembly | | |

### DETAILED DESCRIPTION OF THE EMBODIMENTS

To make the purpose, technical solutions, and advantages of the present disclosure clearer, the technical solutions of the present disclosure are clearly and completely described below in conjunction with the specific embodiments of the present disclosure and the corresponding accompanying drawings. Obviously, the described embodiments are only some embodiments of the present disclosure, not all embodiments. Based on embodiments of the present disclosure, all other embodiments obtained by those of ordinary skill in the art without creative efforts fall within the scope of the present disclosure.

In the description of the present disclosure, it should be noted that unless otherwise explicitly specified and defined, the terms “installation,” “connection,” and “linkage” should be understood in a broad sense. For example, the connection can be a fixed connection, a detachable connection, or an integrated connection; a direct connection or an indirect connection through an intermediate medium; or an internal communication between two elements. For those of ordinary skill in the art, the specific meaning of the above terms in the present disclosure can be understood based on the specific situations.

Additionally, although the terms used in the present disclosure are chosen from known and commonly used terms, some terms in the description of the present disclosure may be selected by the applicant according to his or her judgment. The detailed meanings are explained in the relevant parts of the present description.

Furthermore, the claims should be understood not only through the actual terms used but also through the implications contained in the terms.

To allow those skilled in the art to better understand the inventive concept of the present disclosure, it is necessary to briefly introduce other solutions for driving the induction coil assembly to move up and down in the related technology.

In the related technology, a dual-motor and bidirectional clutch, combined with a multi-stage decelerator and a multi-stage synchronous belt transmission, can form a fast and slow lifting positioning system to drive the induction coil assembly to move up and down. The dual motors include a slow motor and a fast motor. The multi-stage synchronous belt transmission includes a first synchronous belt, a second synchronous belt, and a third synchronous belt. The multi-stage decelerator includes a first decelerator and a second decelerator.

The slow motor can be directly connected to the first decelerator, connected to a lower input end of the bidirectional clutch through the first synchronous belt, and connected to the second decelerator and the lifting assembly through the third synchronous belt to form a slow lifting positioning mechanism. The fast motor can be connected to an upper input end of the bidirectional clutch through the second synchronous belt and connected to the second decelerator and the lifting assembly through the third synchronous belt to form a fast lifting positioning mechanism. Then, by controlling the power-on or power-off of the clutch at the upper and lower input ends of the bidirectional clutch, the switching between a fast speed and a slow speed can be achieved.

For example, when the induction coil assembly needs to be driven to move up and down at a slow speed, the slow motor can output power through the bidirectional clutch while the power of the fast motor can be cut off. When the induction coil assembly needs to be driven to move up and down at a fast speed, the fast motor can output power through the bidirectional clutch while the power of the slow motor can be cut off.

In the solutions of the related technology, the power of the motor can be transmitted to the lifting assembly by being connected to two stages of synchronous belts. Since belt transmission is flexible transmission, the transmission precision as a gear cannot be achieved. Moreover, when the number of stages of the belt transmission is larger, a cumulative lifting positioning error can be larger compared to the gear transmission. Thus, in the solution of the related technology, the structure is complex, and the precision is not high.

The technical solutions of embodiments of the present disclosure are described in detail in connection with the accompanying drawings.

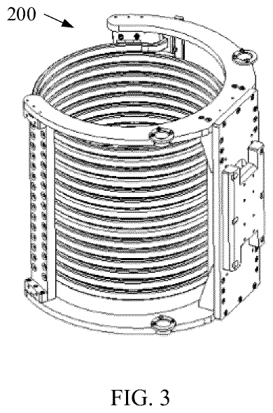

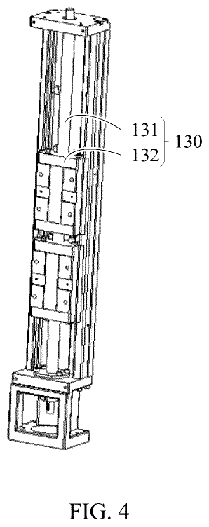

Embodiments of the present disclosure provide an induction coil assembly drive system. The induction coil assembly drive system can be applied to the semiconductor processing equipment. As shown in FIG. 2 to FIG. 5, the induction coil assembly drive system 100 includes a rotary driver 110, a lifting assembly 130, and a controller 150.

The rotary driver 110 can drive and be connected to the lifting assembly 130. The lifting assembly 130 can be configured to drive and be connected to the induction coil assembly 200 to drive the induction coil assembly 200 to move up and down.

The controller 150 can be configured to determine a theoretical speed of the rotary driver 110 based on a target lifting speed of the induction coil assembly 200 within a preset time length. The theoretical speed can be a constant speed when the rotatory driver 110 moves in the predetermined time length. The controller 150 can also be configured to determine whether the theoretical rotation speed of the rotary driver 110 is less than or equal to a predetermined rotation speed. The predetermined rotation speed can be a critical rotation speed at which the rotary driver 110 generates vibration. When the theoretical rotation speed of the rotary driver 110 is less than or equal to the predetermined rotation speed, the controller 150 can be further configured to control the rotary driver 110 to alternately stop and operate at the target speed within the predetermined time length to cause the average rotation speed of the rotary driver 110 to be equal to the theoretical rotation speed within the predetermined time length. The target rotation speed can be greater than the predetermined rotation speed.

In embodiments of the present disclosure, the rotary driver 110 can alternately stop and operate at the target rotation speed to cause the average rotation speed of the rotary driver 110 to be equal to the theoretical rotation speed in the predetermined time length. Thus, the lifting speed of the induction coil assembly 200 can satisfy the needs. When the rotary driver 110 operates at the target rotation speed, the target rotation speed can be greater than the critical rotation speed at which the rotary driver 110 generates the vibration. Then, the rotary driver 110 can be prevented from generating the vibration to improve the drive precision of the rotary driver 110. Then, the rotary driver 110 and the lifting assembly 130 can be configured to drive the induction coil assembly 200 to move up and down precisely.

It should also be noted that compared to the solutions in the related technology, in the solution of the present disclosure, the clutch may not need to be configured to perform switching. One rotary driver 110 can control the induction coil assembly 200 to perform quick positioning and slow positioning. The structure can be simple, the installation can be convenient, and the cost of the hardware can be low.

In embodiments of the present disclosure, the controller 150 can be further configured to, when the theoretical rotation speed of the rotary driver 110 is less than or equal to the predetermined rotation speed, control within the preset time length the number of times the rotary driver 110 switches to a stop state to be a plurality of times, and the rotary driver 110 to remain the first time length each time in the stop state. The number of times that the rotary driver 110 switches to a state of operating at the target rotation speed can be the same as the number of times that the rotary driver 110 switches to the stop state. The rotary driver 110 can remain a second time length each time at the state of operating at the target rotation speed. The sum of the cumulative time length of the rotary driver 110 being in the stop state (the product of the number of times in the stop state and the first time length) and the cumulative time length of rotary driver 110 being in the state of operating at the target rotation speed (the product of the number of times in the state of operating at the target rotation speed and the second time length) can be equal to the predetermined time length.

For example, if the predetermined time length is T, the theoretical rotation speed of the rotary driver 110 can be V₀, the target rotation speed of the rotary driver 110 can be V₁, the time for the rotary driver 110 to operate at the target speed V₁ for a single time can be T₁, and the time for the rotary driver 110 to stop can be T₂ for a single time. The number of times for rotary driver 110 to alternatively operate can be N, where T=N (T₁+T₂) and V₀=NV₁×T₁/T.

In embodiments of the present disclosure, the controller 150 can also be configured to, when the theoretical rotation speed is greater than the predetermined rotation speed, control the rotary driver 110 to operate at the theoretical rotation speed within the predetermined time length to drive the induction coil assembly 200 to move up and down. That is, in embodiments of the present disclosure, when the theoretical rotation speed is greater than the critical rotation speed at which the rotary driver 110 generates vibration, the rotary driver 110 can directly operate at a constant rotation speed to reduce the control difficulty of the controller 150.

In embodiments of the present disclosure, the lifting assembly 130 can include a screw rod 131 and a slider 132. The slider 132 can be threadedly connected to the screw rod 131. Thus, the rotary screw rod 131 can be configured to drive the slider 132 to move along an extension direction of the screw rod 131. The rotary driver 110 can drive and be connected to the screw rod 131. The rotary driver 110 can be configured to drive the screw rod 131. The slider 132 can be configured to be connected to the induction coil assembly 200. The rotary driver 110 can drive the screw rod 131 to rotate. Then, the rotary screw rod 131 can drive the slider 132 to move. Thus, the slider 132 can drive the induction coil assembly 200 to move up and down.

In addition, in embodiments of the present disclosure, the lifting assembly 130 can include a cam and a pushrod. The rotary driver 110 can drive and be connected to the cam to drive the cam to rotate. The rotating cam can drive the pushrod to move up and down. Then, the pushrod moving up and down can drive the induction coil assembly 200 to move up and down.

In embodiments of the present disclosure, the induction coil assembly drive system 100 can further include a decelerator 120. The rotary driver 110 can drive and be connected to the screw rod 131 through the decelerator 120.

As shown in FIG. 2, in embodiments of the present disclosure, the decelerator 120 includes a first sub-decelerator 121 and a second sub-decelerator 122. The second sub-decelerator 122 can be a reversing decelerator. That is, the decelerator 120 can switch between two opposite rotation directions. The second sub-decelerator 122 can include a second power output shaft. The rotary driver 110 can drive and be connected to the first sub-decelerator 121, and the first sub-decelerator 121 and the second sub-decelerator 122 can be drivingly connected. The second power output shaft can be arranged in the height direction of the induction coil assembly drive system 100. The screw rod 131 can be coaxially connected to the second power output shaft. Then, the screw rod 131 can be arranged in a vertical direction to facilitate the vertically arranged screw rod 131 to drive the slider 132 threadedly connected to the screw rod 131 to move up and down. Thus, the induction coil assembly 200 can move up and down with the slider 132.

For example, in embodiments of the present disclosure, both the first sub-decelerator 121 and the second sub-decelerator 122 can be gear decelerators.

In embodiments of the present disclosure, the first sub-decelerator 121 can include a first power output shaft, and the induction coil assembly drive system 100 can further include an Electromagnetic brake 140. The Electromagnetic brake 140 can include a magnetic fixing member 141 and a magnetic adsorption member 142. The magnetic adsorption member 142 can be circumferentially connected to the first power output shaft in a position-limiting manner. When the Electromagnetic brake 140 switches from a power-on state to a power-off state, the magnetic adsorption member 142 and the magnetic fixing member 141 can switch from a separated state to an adsorption state. Then, when it needs to cause the induction coil assembly 200 to stop moving up and down, the Electromagnetic brake 140 can be in the power-off state. Thus, the Electromagnetic brake 140 can be configured to brake the first power output shaft of the first sub-decelerator 121 to cause the first power output shaft to stop rotating to cut off the power transferred to the induction coil assembly 200. When the induction coil assembly 200 needs to move up and down, the Electromagnetic brake 140 can be in the power-on state. Then, the magnetic adsorption member 142 and the magnetic fixing member 141 can be in a separated state. Thus, the Electromagnetic brake 140 can be separated from the first power output shaft of the first sub-decelerator 121 to allow the first power output shaft to rotate normally to transfer the power to the induction coil assembly 200.

In embodiments of the present disclosure, the first sub-decelerator 121 can include a first power input shaft. The rotary driver 110 can drive and be connected to the first power input shaft to transfer the power output by the rotary driver 110 to the first sub-decelerator 121.

In embodiments of the present disclosure, the second sub-decelerator 122 can include a second power input shaft. The first power output shaft of the first sub-decelerator 121 can drive and be connected to the second power input shaft through a first coupling and a transmission shaft in sequence. Then, the power output by the rotary driver 110 can be transferred to the second sub-decelerator 122 through the first sub-decelerator 121, the first coupling, and the transmission shaft in sequence.

Furthermore, the second power output shaft of the second sub-decelerator 122 can drive and be connected to the screw rod 131 through the second coupling. Thus, the power output by the rotary driver 110 can be transferred to the screw rod 131. Then, the rotary screw rod 131 can be configured to drive the slider 132 threadedly connected to the screw rod 131 to move up and down to allow the induction coil assembly 200 to move up and down with the slider 132.

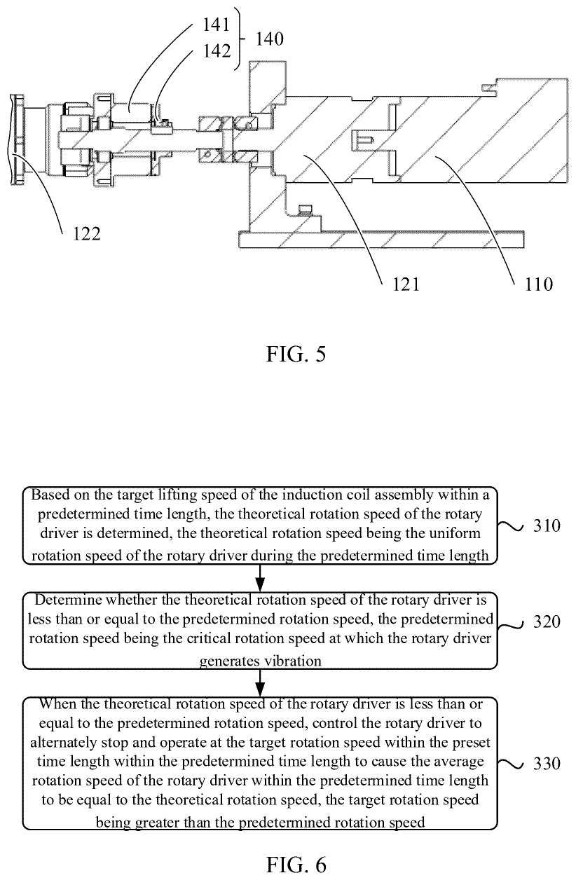

As shown in FIG. 5, the drive shaft connecting the first sub-decelerator 121 and the second sub-decelerator 122 includes an Electromagnetic brake 140. The magnetic adsorption member 142 of the Electromagnetic brake 140 is connected to the drive shaft via a key. The magnetic fixing member 141 is fixedly connected to the housing of the second sub-decelerator 122. After the system is powered on, the magnetic adsorption member 142 and the magnetic fixing member 141 of the Electromagnetic brake 140 can be separated. The drive shaft can transfer the power to the screw rod 131 of the lifting assembly 130 when driven by the rotary driver 110.

After the system is powered off, the magnetic adsorption member 142 and the magnetic fixing member 141 of the Electromagnetic brake 140 can be engaged with each other. Since the magnetic fixing member 141 is fixedly connected to the housing of the second sub-decelerator 122, and the housing of the second sub-decelerator 122 is fixedly connected to the fixed frame of the lifting assembly 130. The fixed frame of the lifting assembly 130 can be fixedly connected to the frame of the whole machine. Thus, when brake and the power-off is invalid for the rotary driver 110, the induction coil assembly 200 can be prevented from falling abruptly due to the weight. Then, the safety of the induction coil assembly drive system 100 can be improved.

In other embodiments of the present disclosure, when the induction coil assembly drive device includes the Electromagnetic brake 140, the magnetic adsorption member 142 of the Electromagnetic brake 140 can also be connected to the screw rod 131. When the Electromagnetic brake 140 switches from the power-on state to the power-off state, the magnetic adsorption member 142 can switch from a separated state to an engaged state with the magnetic fixing member 141 of the Electromagnetic brake 140. Then, when the brake and power-off are invalid for the rotary driver 110, the induction coil assembly can be prevented from falling abruptly due to the weight of the induction coil assembly 200. Thus, the safety of the induction coil assembly drive system 100 can be improved.

As shown in FIG. 2, in embodiments of the present disclosure, the lifting assembly 130 includes a screw rod 131 and a slider 132. The induction coil assembly drive system 100 further includes a rotary encoder 160. The rotary encoder 160 can be connected to the screw rod 131. The rotary encoder 160 can be electrically connected to the controller 150. Then, the rotary encoder 160 can be configured to obtain the rotation speed of the screw rod 131 to determine the moving speed of the slider 132 based on the rotation speed of the screw rod 131. Further, the moving speed of the slider 132 detected by the rotary encoder 160 can be fed back to the controller 150. Then, the controller 150 can perform closed-ring control on the moving speed of the slider to improve the drive precision for the induction coil assembly 200 to move up and down.

To facilitate description, for example, the rotary driver 110 can be a servo motor, and the controller 150 can be a servo controller of the servo motor. The operation principle of the induction coil assembly drive system 100 can be described below.

When the rotary driver 110 is a servo motor and the controller 150 is a servo controller of the servo motor, the servo controller can send a pulse signal to the servo motor. By controlling a pulse frequency and a number of pulses, the rotation speed of the servo motor can be controlled, thereby controlling the lifting speed of the induction coil assembly 200.

For example, the pitch of the screw rod 131 of the lifting assembly 130 can be h, and a two-stage reduction ratio formed by the first sub-decelerator 121 and the second sub-decelerator 122 can be i. In an initial stage of a crystal growth process, the average speed of the quick positioning of the induction coil assembly 200 can be V_{fast}, and the rotation speed of the rotary driver 110 may need to be adjusted to R_{fast}=iV_{fast}/h. During the process stage, when the average speed required for the slow positioning of the induction coil assembly 200 is V_{slow min}, the rotation speed of the rotary driver 110 may need to be adjusted to R_{slow min}=iV_{slow min}/h. When the average speed required for the slow positioning is V_{slow max}, the rotation speed of the rotary driver 110 may need to be adjusted to R_{slow max}=iV_{slow max}/h.

In practice, V_{slow max} and V_{slow min} can have a difference of an order of magnitude of 10 to 10³, V_{fast} and V_{slow min} can have a difference of an order of magnitude of 10⁴. V_{fast} and V_{slow max} can have a difference of an order of magnitude of 10. That is, the rotation speed range of the rotary driver 110 can be from V_{slow min} to V_{fast}, which have a difference of an order of magnitude of 10⁴.

Since the transmission system is not a completely rigid structure, and the load of the induction coil assembly 200 is relatively heavy with a large inertia, when the rotation speed of the rotary driver 110 decreases to a certain value, elastic twisting of the transmission mechanism between the motor and the load can occur, causing the induction coil assembly 200 to have occasional vibrations at the load end. The vibration of the induction coil assembly 200 can be measured experimentally. In embodiments of the present disclosure, the critical rotation speed at which the rotary driver 110 generates vibrations is denoted as R_{critical}. The value of R_{critical} can be related to the weight of the load of the transmission structure. After conversion, the average speed of the lifting positioning of the induction coil assembly 200 can be V_{critical}=R_{critical}*h/i. Actual tests show that V_{slow min}<V_{critical}<V_{slow max}<V_{fast}, corresponding to the rotation speed of the rotary driver 110 as R_{slow min}<R_{critical}<R_{slow max}<R_{fast}.

In the solution of embodiments of the present disclosure, the controller 150 can adjust the alternating motion of the rotary driver 110 between movement and stillness, allowing the rotary driver 110 to drive the induction coil assembly 200 to achieve fast and slow positioning within the speed adjustment range from V_{slow min} to V_{fast} with a difference of an order of magnitude of 10⁴. The slow-speed adjustment range can be V_{slow min} to V_{slow max}, with a difference of an order of magnitude of 10 to 10³.

For example, when the induction coil assembly 200 needs to perform slow positioning at an average speed of V_{slow min} within time T, the time T can be divided into N groups of time T₁ and T₂, that is, T=N (T₁+T₂). During time T₁, the rotation speed of the rotary driver 110 can be adjusted to R₁>R_{critical}. During time T₂, the rotary driver 110 can be kept stationary. According to R_{slow min} calculated from the required average speed V_{slow min} for the slow positioning of the induction coil assembly 200, the ratio of T₁ to T₂ and the values of N and R₁ can be adjusted according to R_{slow min}. Thus, R_{slow min}=NT₁R₁/T. Then, the rotary driver 110 can drive the induction coil assembly 200 for slow positioning at V_{slow min}.

To enable those skilled in the art to better understand the solution of embodiments of the present disclosure, more specific embodiments can be provided below for reference.

In embodiments of the present disclosure, the pitch of the screw rod 131 of the lifting assembly 130 can be h=5 mm, the total reduction ratio of the first sub-decelerator 121 and the second sub-decelerator 122 can be i=600, and the maximum rotation speed of the rotary driver 110 is R_{fast}=6000 r/min. In the initial stage of the crystal growth process, the maximum average speed for the fast positioning of the induction coil assembly 200 can be V_{fast max}=50 mm/min.

Through testing, when the rotation speed of the rotary driver 110 drops below R_{critical}=1 r/min=60 r/h, and the positioning speed of the induction coil assembly 200 drops to 0.5 mm/h, occasional vibrations may occur during the lifting process.

If the average speed range of fast and slow positioning of the induction coil assembly 200 needs to be 1 to 30 mm/min, that is, V_{fast}=30 mm/min, V_{slow max}=1 mm/min, and the difference between V_{fast} and V_{slow max} is 30 times, the rotation speed range of the rotary driver 110 may need to be adjusted to 120 to 3600 r/min. That is, R_{fast}=3600 r/min, R_{slow max}=120 r/min>R_{critical}. Thus, the rotary driver 110 can operate at a uniform speed with the theoretical rotation speed.

If the average speed range of fast and slow positioning of the induction coil assembly 200 needs to be 0.05 mm/h to 30 mm/min, that is, V_{fast}=30 mm/min, V_{slow min}=0.05 mm/h, and the difference between V_{fast} and V_{slow min} is 36,000 times, the difference between V_{slow max} and V_{slow min} is 1,200 times. Thus, the rotation speed range of the rotary driver 110 may need to be adjusted to 6 r/h to 3600 r/min. That is, R_{fast}=3600 r/min, R_{slow min}=6 r/h<R_{critical}.

When the rotary driver 110 rotates uniformly at R_{slow min}=6 r/h, occasional vibrations may occur while the rotary driver 110 drives the induction coil assembly 200 to move up and down. With the solution of embodiments of the present disclosure, the rotary driver 110 can be controlled to alternate between stillness and movement to allow the rotary driver 110 to drive the induction coil assembly 200 for slow positioning with the average speed at V_{slow min}=0.05 mm/h.

It can be understood that if the induction coil assembly 200 performs slow positioning by 0.05 mm within 1 hour, time T=1 h=60 min can be divided into N groups of T₁ and T₂. The rotary driver 110 can be controlled to operate at a rotation speed of R₁=2 r/min>R_{critical} during T₁, and stay still during T₂.

According to the average speed V_{slow min}=0.05 mm/h for the slow positioning of the induction coil assembly 200, R_{slow min}=6 r/h can be calculated. According to R₁=2 r/min and R_{slow min}=6 r/h, and the actual needs of the crystal growth process, T₁, T₂, and N can be adjusted. For example, T=1 h=60 min can be divided into N=6 groups of T₁ and T₂, where T₁=0.5 min, T₂=9.5 min, such that R_{slow min}=NT₁R₁/T=0.1 r/min=6 r/h. Thus, the rotary driver 110 can drive the induction coil assembly 200 to perform slow positioning at an average speed of V_{slow min}=0.05 mm/h.

In embodiments of the present disclosure, the induction coil assembly 200 can be fixedly connected to the slider 132 of the lifting assembly 130 through an adapter plate. The slider 132 can drive the induction coil assembly 200 to perform lifting and positioning. The rotary encoder 160 can be connected to the top end of the screw rod 131 of the lifting assembly 130 through the third coupling. The rotary encoder 160 can be configured to detect a turning angle of the screw rod 131 of the lifting assembly 130 to determine a lifting displacement and speed of the induction coil assembly 200 and to feed the lifting displacement and a speed signal of the induction coil assembly 200 back to the controller 150. The controller 150 can compare the displacement and speed feedback from the rotary encoder 160 with a set displacement and speed. After calculation, a drive pulse can be converted and sent to the rotary driver 110 for compensation. Then, the positioning precision of the induction coil assembly drive system 100 can be significantly improved.

For example, the rotary driver 110 may need to drive the induction coil assembly 200 to perform slow positioning by 60 mm at an average speed of V_{slow max}=1 mm/min within a certain time. That is, the rotary driver 110 needs to rotate at an average speed of R_{slow max}=120 r/min to achieve 7200 rotations, and the screw rod 131 of the lifting assembly 130 needs to rotate synchronously with the rotary driver 110. During the process of the screw rod 131 achieves 7200 rotations, the rotary encoder 160 can detect an actual rotation count in real time and feed the detection data back to the controller 150. Assume that when the rotary driver 110 is supposed to rotate 1200 rotations, the rotary encoder 160 detects that the screw rod 131 rotates 1,199 rotations. The rotary encoder 160 can then feed the detected data back to the controller 150. The controller 150 can perform motion compensation on the rotary driver 110 to ensure the positioning accuracy.

Embodiments of the present disclosure provide a control method for an induction coil assembly drive system. The induction coil assembly drive system can be any induction coil assembly drive system 100 of embodiments of the present disclosure.

As shown in FIG. 6, the control method of the induction coil assembly drive system of embodiments of the present disclosure includes the following steps.

At 310, based on the target lifting speed of the induction coil assembly within a predetermined time length, the theoretical rotation speed of the rotary driver is determined. The theoretical rotation speed is the uniform rotation speed of the rotary driver during the predetermined time length.

For example, in embodiments of the present disclosure, based on the target lifting speed of the induction coil assembly 200 in the predetermined time length, the controller 150 can determine the theoretical rotation speed of the rotary driver. The theoretical rotation speed can be a uniform speed at which the rotary driver 110 operates in the predetermined time length.

At 320, whether the theoretical rotation speed of the rotary driver is smaller than or equal to the predetermined rotation speed is determined. The predetermined rotation speed can be a critical rotation speed at which the rotary driver generates vibration.

For example, in embodiments of the present disclosure, the controller 150 can be configured to determine whether the theoretical rotation speed of the rotary driver 110 is less than or equal to the predetermined rotation speed. The predetermined rotation speed can be the critical rotation speed at which the rotary driver 110 generates vibration.

At 330, when the theoretical rotation speed of the rotary driver is less than or equal to the predetermined rotation speed, the rotary driver is controlled to alternately stop and operate at the target rotation speed within the preset time length within the predetermined time length to cause the average rotation speed of the rotary driver within the predetermined time length to be equal to the theoretical rotation speed. The target rotation speed is greater than the predetermined rotation speed.

For example, in embodiments of the present disclosure, when the theoretical rotation speed of the rotary driver 110 is less than or equal to the predetermined rotation speed, the controller 150 can be configured to control the rotary driver 110 to alternately stop and operate at the target speed within the predetermined time length within the predetermined time length to cause the average rotation speed of the rotary driver 110 to be equal to the theoretical rotation speed within the predetermined time length. The target rotation speed can be greater than the predetermined rotation speed.

Further, in embodiments of the present disclosure, the control method of the induction coil assembly drive system can further include:
when the theoretical rotation speed is greater than the predetermined rotation speed, controlling the rotary driver to operate at the theoretical rotation speed within the predetermined time length to drive the induction coil assembly to move up and down.

For example, in embodiments of the present disclosure, the controller 150 can be configured to control the rotary driver 110 to operate at the theoretical speed within the predetermined time length to drive the induction coil assembly 200 to move up and down.

Embodiments of the present disclosure provide semiconductor processing equipment, including an induction coil assembly drive system 100. The induction coil assembly drive system 100 can include:
a rotary driver 110;
a lifting assembly 130, the rotary driver 110 being drivingly connected to the lifting assembly 130, and the lifting assembly 130 being configured to be drivingly connected to the induction coil assembly 200 to drive the induction coil assembly 200 to move up and down; and
a controller 150, including a processor and a readable storage medium, the readable storage medium storing programs or instructions, and the processor executing the programs or instructions to realize the following control method of:
determining the theoretical rotation speed of the rotary driver 110 based on the target lifting speed of the induction coil assembly 200 within the predetermined time length, wherein the theoretical speed is a speed at which the rotary driver 110 uniformly operates within the predetermined time length;
determining whether the theoretical speed of the rotary driver 110 is less than or equal to the predetermined rotation speed, wherein the predetermined rotation speed is the critical speed at which the rotary driver 110 generates vibration; and
if the theoretical speed of the rotary driver 110 is less than or equal to the predetermined rotation speed, controlling the rotary driver 110 to alternately stop and operate at the target rotation speed within the predetermined time length, so that the average speed of the rotary driver 110 within the predetermined time length is equal to the theoretical speed, wherein the target speed is greater than the predetermined rotation speed.

Embodiments of the present disclosure provide a readable storage medium. The readable storage medium stores programs or instructions that, when executed by the processor, cause the processor to implement steps of any control method of the induction coil assembly of embodiments of the present disclosure.

Thus, in embodiments of the present disclosure, the rotary driver 110 can alternately stop and operate at the target rotation speed, so that the average speed of the rotary driver 110 within the predetermined time length can be equal to the theoretical speed to ensure that the lifting speed of the induction coil assembly 200 meets the requirements. When the rotary driver 110 operates at the target speed, the target speed can be greater than the critical speed at which the rotary driver 110 generates vibration. Then, the rotary driver 110 can be prevented from vibrating. Thus, the drive precision of the rotary driver 110 can be improved. Therefore, the rotary driver 110 and the lifting assembly 130 can be configured to drive the induction coil assembly 200 to precisely move up and down.

It should be noted that, in the present specification, relationship terms such as “first” and “second” are only used to distinguish one entity or operation from another, and do not necessarily require or imply any actual relationship or order between these entities or operations. Moreover, the terms “include,” “comprise,” or any other variation thereof are intended to encompass non-exclusive inclusion, so that a process, method, article, or equipment that includes a series of elements not only includes those elements, but may also include other elements not explicitly listed, or further includes elements inherent to such process, method, article, or equipment.

Although embodiments of the present disclosure have been shown and described, those of ordinary skill in the art should understand that various changes, modifications, substitutions, and variations can be made to these embodiments without departing from the principles and spirit of the present disclosure. The scope of the present disclosure is defined by the appended claims and their equivalents.

1. An induction coil assembly drive system, applied to semiconductor processing equipment, comprising:
a rotary driver; and
a lifting assembly, the rotary driver being drivingly connected to the lifting assembly, and the lifting assembly being configured to be transmission-connected to an induction coil assembly to drive the induction coil assembly to move up and down;
a controller configured to:
determine a theoretical rotation speed of the rotary driver based on a target lifting speed of the induction coil assembly within a predetermined time length, wherein the theoretical rotation speed is a speed at which the rotary driver operates uniformly within the predetermined time length;
determine whether the theoretical rotation speed of the rotary driver is less than or equal to a predetermined rotation speed, wherein the predetermined rotation speed is a critical rotation speed at which the rotary driver generates vibration; and
in response to the theoretical rotation speed of the rotary driver being less than or equal to the predetermined rotation speed, control the rotary driver to alternately stop and operate at the target rotation speed within the predetermined time length to cause an average speed of the rotary driver within the predetermine time length to be equal to the theoretical rotation speed, wherein the target rotation speed is greater than the predetermined rotation speed.

2. The induction coil assembly drive system according to claim 1, wherein the controller is further configured to, within the predetermined time length in response to the theoretical rotation speed of the rotary driver being less than or equal to the predetermined rotation speed:
control the rotary driver to switch to a stop state for a plurality of times, wherein the rotary driver remains a first time length each time in the stop state; and
control a number of times for the rotary driver switching to operate at the target rotation speed to be same as a number of times for the rotary driver switching to stop, wherein the rotary driver remains a second time length in an operation state at the target rotation speed each time;
wherein a sum of a cumulative time length of the rotary driver being in the stop state and a cumulative time length of the rotary driver being in the operation state is equal to the predetermined time length.

3. The induction coil assembly drive system according to claim 1, wherein the controller is further configured to control the rotary driver to operate at the theoretical rotation speed within the predetermined time length in response to the theoretical rotation speed being greater than the predetermined rotation speed to drive the induction coil assembly to move up and down.

4. The induction coil assembly drive system according to claim 1, wherein the lifting assembly includes a screw rod and a slider, wherein the slider is threadedly connected to the screw rod to drive the slider to move using the rotating screw rod; and
the rotary driver is drivingly connected to the screw rod to drive the screw rod to rotate, and the slider is configured to be connected to the induction coil assembly.

5. The induction coil assembly drive system according to claim 4, wherein the induction coil assembly drive system further includes a rotary encoder, wherein the rotary encoder is connected to the screw rod and electrically connected to the controller.

6. The induction coil assembly drive system according to claim 4, wherein the induction coil assembly drive system further includes a decelerator, wherein the rotary driver is drivingly connected to the screw rod through the decelerator.

7. The induction coil assembly drive system according to claim 6, wherein the decelerator includes a first sub-decelerator and a second sub-decelerator, wherein the second sub-decelerator is a reversing decelerator and includes a second power output shaft;
the rotary driver is drivingly connected to the first sub-decelerator, the first sub-decelerator is drivingly connected to the second sub-decelerator, the second power output shaft is arranged along a height direction of the induction coil assembly drive system, and the screw rod is coaxially connected to the second power output shaft.

8. The induction coil assembly drive system according to claim 7, wherein the first sub-decelerator includes a first power output shaft, and the induction coil assembly drive system further includes an Electromagnetic brake, the Electromagnetic brake including a magnetic fixing member and a magnetic adsorption member, the magnetic adsorption member being circumferentially connected to the first power output shaft in a position-limiting manner, when the electromagnetic brake switches from a power-on state to a power-off state, the magnetic adsorption member switching from a separated state to an engaged state with the magnetic fixing member.

9. A control method for an induction coil assembly drive system, comprising:
determining a theoretical rotation speed of a rotary driver by a controller based on a target lifting speed of an induction coil assembly within a predetermined time length, the theoretical rotation speed being a speed at which the rotary driver uniformly operates within the predetermined time length;
determining whether the theoretical rotation speed of the rotary driver is less than or equal to the predetermined rotation speed by the controller, wherein the predetermined rotation speed is a critical speed at which the rotary driver generates vibration; and
in response to the theoretical rotation speed of the rotary driver being less than or equal to the predetermined rotation speed, controlling the rotary driver to alternately stop and operate at the target rotation speed within the predetermined time length by the controller to cause the average rotation speed of the rotary driver within the predetermined time length to be equal to the theoretical rotation speed, wherein the target speed is greater than the predetermined rotation speed.

10. The control method of the induction coil assembly drive system according to claim 9, wherein the control method of the induction coil assembly drive system further includes:
in response to the theoretical rotation speed being greater than the predetermined rotation speed, controlling the rotary driver to operate at the theoretical rotation speed within the predetermined time length to drive the induction coil assembly to move up and down by the controller.

11. Semiconductor processing equipment, comprising an induction coil assembly drive system, wherein the induction coil assembly drive system includes:
a rotary driver; and
a lifting assembly, the rotary driver being drivingly connected to the lifting assembly, and the lifting assembly being configured to be transmission-connected to an induction coil assembly to drive the induction coil assembly to move up and down;
a controller including a processor and a readable storage medium, the readable storage medium storing a program or an instruction that, when executed by the processor, causes the processor to:
determine a theoretical rotation speed of the rotary driver based on a target lifting speed of the induction coil assembly within a predetermined time length, wherein the theoretical rotation speed is a speed at which the rotary driver operates uniformly within the predetermined time length;
determine whether the theoretical rotation speed of the rotary driver is less than or equal to a predetermined rotation speed, wherein the predetermined rotation speed is a critical rotation speed at which the rotary driver generates vibration; and
in response to the theoretical rotation speed of the rotary driver being less than or equal to the predetermined rotation speed, control the rotary driver to alternately stop and operate at the target rotation speed within the predetermined time length to cause an average speed of the rotary driver within the predetermine time length to be equal to the theoretical rotation speed, wherein the target rotation speed is greater than the predetermined rotation speed.

12. The semiconductor processing equipment according to claim 11, wherein the controller is further configured to, within the predetermined time length in response to the theoretical rotation speed of the rotary driver being less than or equal to the predetermined rotation speed:
control the rotary driver to switch to a stop state for a plurality of times, wherein the rotary driver remains a first time length each time in the stop state; and
control a number of times for the rotary driver switching to operate at the target rotation speed to be same as a number of times for the rotary driver switching to stop, wherein the rotary driver remains a second time length in an operation state at the target rotation speed each time;
wherein a sum of a cumulative time length of the rotary driver being in the stop state and a cumulative time length of the rotary driver being in the operation state is equal to the predetermined time length.

13. The semiconductor processing equipment according to claim 11, wherein the controller is further configured to control the rotary driver to operate at the theoretical rotation speed within the predetermined time length in response to the theoretical rotation speed being greater than the predetermined rotation speed to drive the induction coil assembly to move up and down.

14. The semiconductor processing equipment according to claim 11, wherein the lifting assembly includes a screw rod and a slider, wherein the slider is threadedly connected to the screw rod to drive the slider to move using the rotating screw rod; and
the rotary driver is drivingly connected to the screw rod to drive the screw rod to rotate, and the slider is configured to be connected to the induction coil assembly.

15. The semiconductor processing equipment according to claim 14, wherein the induction coil assembly drive system further includes a rotary encoder, wherein the rotary encoder is connected to the screw rod and electrically connected to the controller.

16. The semiconductor processing equipment according to claim 14, wherein the induction coil assembly drive system further includes a decelerator, wherein the rotary driver is drivingly connected to the screw rod through the decelerator.

17. The semiconductor processing equipment according to claim 16, wherein the decelerator includes a first sub-decelerator and a second sub-decelerator, wherein the second sub-decelerator is a reversing decelerator and includes a second power output shaft;
the rotary driver is drivingly connected to the first sub-decelerator, the first sub-decelerator is drivingly connected to the second sub-decelerator, the second power output shaft is arranged along a height direction of the induction coil assembly drive system, and the screw rod is coaxially connected to the second power output shaft.

18. The semiconductor processing equipment according to claim 17, wherein the first sub-decelerator includes a first power output shaft, and the induction coil assembly drive system further includes an Electromagnetic brake, the Electromagnetic brake including a magnetic fixing member and a magnetic adsorption member, the magnetic adsorption member being circumferentially connected to the first power output shaft in a position-limiting manner, when the electromagnetic brake switches from a power-on state to a power-off state, the magnetic adsorption member switching from a separated state to an engaged state with the magnetic fixing member.
